(19) United States
(12) Patent Application Publication
(10) Pub. No.: US 2025/0363273 A1
(43) Pub. Date: Nov. 27, 2025

(54) DESIGN SUPPORT SYSTEM, DESIGN SUPPORT METHOD, AND PROGRAM

(71) Applicant: Hitachi, Ltd., Tokyo (JP)

(72) Inventors: Yoichi ARIMA, Tokyo (JP); Makoto Onodera, Tokyo (JP)

(21) Appl. No.: 19/084,049

(22) Filed: Mar. 19, 2025

(30) Foreign Application Priority Data
May 27, 2024 (JP) 2024-085612

(51) Int. Cl. G06F 30/31

(52) U.S. Cl. CPC G06F 30/31

(57) ABSTRACT

An input information analysis unit that analyzes input information of a user regarding a system model, a model candidate specifying unit that specifies a system model to be generated from system model information in which a plurality of types of templates of the system models is registered, based on an analysis result of the input information, an information extraction unit that extracts necessary information used to generate the system model from a database that stores information regarding design, based on the analysis result of the input information, and a system model generation unit that generates a system model according to the input information, using the extracted necessary information and the template of the system model to be generated are included.

### BACKGROUND

### Technical Field

The present invention relates to a design support system, a design support method, and a program, and particularly, relates to a technology for supporting creation of a system model related to product design.

### Related Art

In recent years, product design has also become complicated as products become complicated, and for example, it is necessary to consider a plurality of regions such as an electric circuit or a strength against vibration. Furthermore, the product design often needs to simultaneously safety not only a performance of the product but also a plurality of key performance indexes (KPI) such as an environmental performance, reliability, or safety. As one of complicated product design methods, utilization of a system model has been proposed.

The system model is obtained by grasping and modeling various regions of the product in a transverse manner and structurally describing the regions. By expressing the product design with the system model, it is possible to eliminate ambiguity of expression due to a natural language and ambiguity of a relationship between elements, and more efficient product design can be expected. Furthermore, by using the system model, for example, when design is changed, an effect of the design change on existing functions or the like is easily specified.

Furthermore, a model-based systems engineering (MBSE) is an evolved form of the system model. In the MBSE, configurations in different regions such as a component structure of the product, a required function, a use case, a design parameter, or a flow of internal processing are associated with each of other and described in a modeling language such as systems modeling language (SysML) so that expression in an image that is visually easy-to-understand can be achieved.

On the other hand, to create the system model including the MBSE model, there is a problem in that advanced specialized knowledge regarding system modeling is required and a large number of man-hours are required. Therefore, there is a demand for a technique for supporting the creation of the system model.

Note that JP 2006-343858 A discloses a technique related to creation of a system model. Specifically, JP 2006-343858 A describes that “a storage device that stores each of a parameter used to create a model, a tool used to create a model, and a model template for a plurality of parts included in a system is provided, the model template of the plurality of parts and the parameter are read according to instruction content input from a user, a model of each part is created by assigning the parameter to the model template of the plurality of parts, and the tool is read and executed, so as to combine the models of the plurality of parts to create a model of a single system”.
Patent document 1 JP 2006-343858 A

### SUMMARY

The technique in JP 2006-343858 A creates a system model of a part by assigning a parameter to a template model of each part, using the template models of the plurality of parts. However, the technique in JP 2006-343858 A does not consider creation of a system model other than the part model. Therefore, with the technique in JP 2006-343858 A, it is considered that it is difficult to solve the above problems, regarding creation of a system model related to a region (category) other than the parts and creation of an MBSE model in which submodels over a plurality of regions are associated.

The present invention has been made in view of the above problems, and an object of the present invention is to reduce a load of a user related to creation of a system model and generate an appropriate system model according to a user's intention.

Although the present application includes a plurality of means for solving at least a part of the problems described above, examples are as follows. A design support system according to one aspect of the present invention that solves the above problems includes an input information analysis unit that analyzes input information of a user regarding a system model, a model candidate specifying unit that specifies a system model to be generated from system model information in which a plurality of types of templates of system models is registered, based on an analysis result of the input information, an information extraction unit that extracts necessary information used to generate the system model from a database that stores information regarding design, based on the analysis result of the input information, and a system model generation unit that generates a system model according to the input information, using the extracted necessary information and the template of the system model to be generated.

According to the present invention, it is possible to reduce a load of a user related to creation of a system model and to generate an appropriate system model according to a user's intention.

Note that problems, configurations, and effects other than the above will be clarified by description of the following embodiments.

### BRIEF DESCRIPTION OF DRAWINGS

FIG. 1 is a diagram illustrating an example of a schematic configuration of a design support system according to a first embodiment;

FIG. 2A is a diagram illustrating an example of system model information;

FIGS. 2B-1 to 2B-3 are diagrams illustrating an example of information registered in an image of a model;

FIG. 3 is a flowchart illustrating an example of design support processing;

FIG. 4A is a diagram for explaining generation of a system model;

FIG. 4B is a diagram illustrating an example of the generated system model;

FIG. 5 is a diagram for explaining generation of a system model including a plurality of submodels;

FIG. 6 is a diagram illustrating an example of a schematic configuration of a design support system according to a modification; and

FIG. 7 is a diagram illustrating an example of a hardware configuration of the design support system.

### DETAILED DESCRIPTION

The following embodiments are an example for describing the present invention, and for clarification of the description, the embodiment is appropriately omitted and simplified. The present invention can be implemented in various other forms. Furthermore, unless otherwise specified, each component may be singular or plural.

Furthermore, for easy understanding of the invention, there is a case where a position, a size, a shape, a range, or the like of each component illustrated in the drawings do not illustrate an actual position, size, shape, range, or the like. Therefore, the present invention is not necessarily limited to the position, the size, the shape, the range, or the like disclosed in the drawings.

Furthermore, as an example of various types of information, expression such as “table”, “list”, or “queue” may be described. However, various types of information may be expressed by a data structure other than these. For example, various types of information such as “XX table”, “XX list”, or “XX queue” may be “XX information”. When identification information is described, expression such as “identification information”, “identifier”, “name”, “ID”, or “number” is used. However, these can be replaced with each other.

Furthermore, in a case where there is a plurality of components having the same or similar functions, description may be given by adding different subscripts to the same reference numeral. Furthermore, in a case where it is not necessary to distinguish these plurality of components from each other, the subscripts may be omitted.

Furthermore, in the embodiments, processing for executing a program may be described. Here, a computer executes a program by a processor (for example, CPU and GPU) and executes processing defined by the program, using a storage resource (for example, memory), an interface device (for example, communication port), or the like. Therefore, a subject of the processing for executing the program may be a processor.

Similarly, the subject of the processing for executing the program may be a controller, a device, a system, a computer, and a node including the processor. It is sufficient for the subject of the processing for executing the program be an arithmetic unit, and the subject may include a dedicated circuit for executing specific processing. Here, the dedicated circuit is, for example, a field programmable gate array (FPGA), an application specific integrated circuit (ASIC), a complex programmable logic device (CPLD), or the like.

The program may be installed from a program source to the computer. The program source may be, for example, a program distribution server or a computer-readable storage medium. In a case where the program source is the program distribution server, the program distribution server includes the processor and a storage resource that stores a program to be distributed, and the processor of the program distribution server may distribute the program to be distributed to another computer. Furthermore, in the embodiments, two or more programs may be implemented as a single program, and a single program may be implemented as two or more programs.

Hereinafter, each embodiment of the present invention will be described with reference to the drawings.

### First Embodiment

### <Outline of Design Support System>

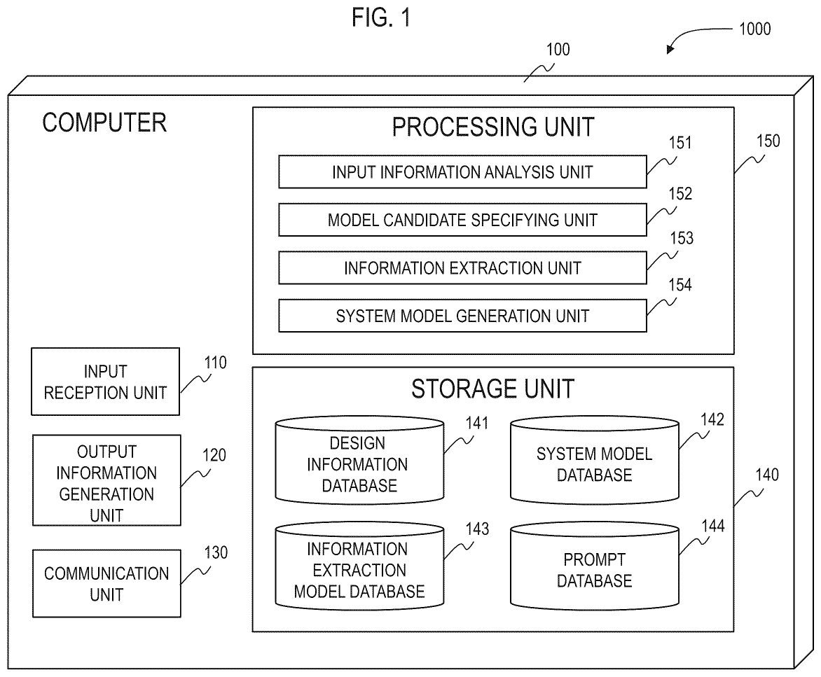

FIG. 1 is a diagram illustrating an example of a schematic configuration of a design support system 1000 according to the present embodiment. The design support system 1000 is a system that is implemented by a computer 100 for executing arithmetic processing and supports user's product design, by generating a system model according to an instruction or a request of a user (for example, designer who designs product or the like).

Specifically, upon receiving input information (for example, instruction or request of user regarding system model. Hereinafter, may be referred to as user input information) from the user regarding the system model, the design support system 1000 analyzes content of the user input information and specifies (select) an appropriate template of the system model from a database, based on the analysis result.

Furthermore, in a case where the specified template of the system model includes a plurality of submodels, the design support system 1000 specifies a correlation between the submodels based on the analysis result of the user input information and associates the submodels.

Furthermore, the design support system 1000 specifies a predetermined prompt based on the analysis result of the user input information and extracts information necessary for generating the system model from a database of design information, using an information extraction model (for example, generative AI).

Furthermore, the design support system 1000 generates and presents a system model according to the request or the like of the user, using the template of the system model and the extracted information.

According to such a design support system 1000, it is possible to reduce a load of the user related to the creation of the system model and generate an appropriate system model according to a user's intention.

### <Functional Configuration of Design Support System 1000>

As illustrated in FIG. 1, the design support system 1000 is implemented by, for example, the computer 100 such as a server device or a personal computer, and includes an input reception unit 110, an output information generation unit 120, a communication unit 130, a storage unit 140, and a processing unit 150.

The input reception unit 110 is a functional unit that receives the user input information regarding the system model, via a predetermined input device (for example, input device included in design support system 1000, such as keyboard or microphone). Specifically, for example, the input reception unit 110 receives the user input information having various contents in natural language, such as “it is desired to check a function defined by a digital camera”, “it is desired to see a relationship between required specifications related to safety and related parts together, when designing a digital camera”, or “it is desired to review a request while ensuring safety of a digital camera and to check a change in a part structure that affects the request”. Note that an information format of the user input information may be text input or voice input.

For example, the output information generation unit 120 is a functional unit that generates various types of output information such as screen information for receiving the user input information or screen information indicating a calculation result of the generated system model or the like. Furthermore, the output information generation unit 120 outputs the generated output information to an output device (for example, display or the like) included in the design support system 1000.

The communication unit 130 is a functional unit that performs information communication with an external device (for example, external device such as cloud server or terminal device used by user). Specifically, the communication unit 130 acquires various types of information used for the arithmetic processing of the design support system 1000 from the external device via a network. Furthermore, the communication unit 130 transmits the information generated by the design support system 1000 to the external device, via the network.

The storage unit 140 is a functional unit that stores various types of information. Specifically, the storage unit 140 includes a design information database 141, a system model database 142, an information extraction model database 143, and a prompt database 144.

The design information database 141 stores various types of information regarding design. Specifically, the design information database 141 stores various types of design information (for example, required specifications, function definition document, part information, design study document, standard information, product information, computer-aided design (CAD), bill of materials (BOM), product defect information, or the like).

The system model database 142 stores system model information in which templates of a plurality of types of system models are registered. The system model information includes a template defining each system model.

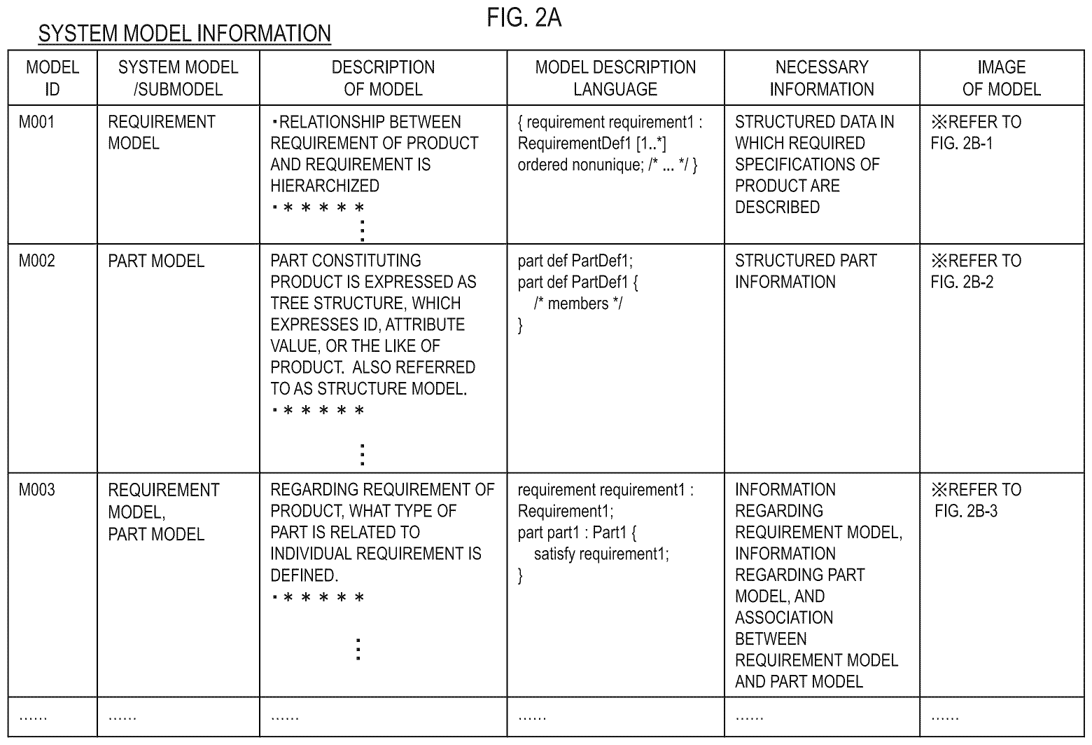

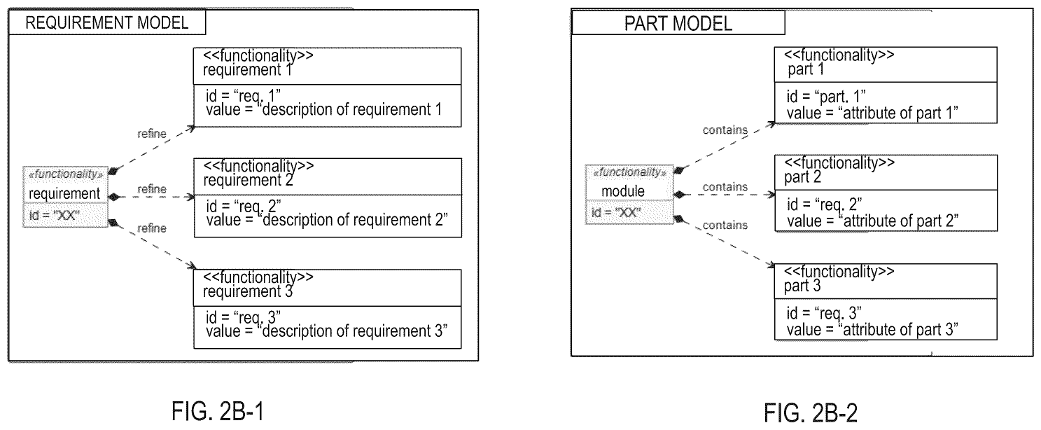

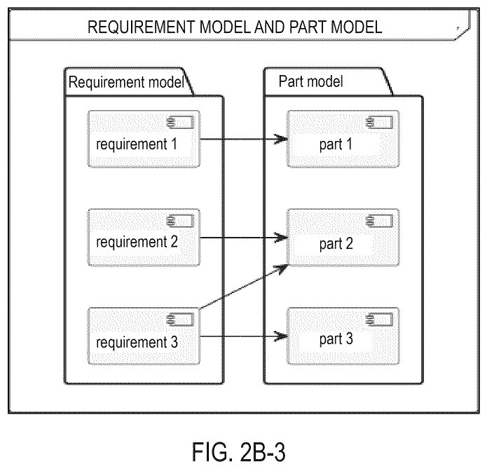

FIG. 2A is a diagram illustrating an example of the system model information. As illustrated, in system model information 200, system model/submodel, description of a model, a model description language, necessary information, and an image of the model are registered as the template of each system model, for each model ID used to identify the type of each system model.

Note that, in the system model/submodel, information indicating a type of the system model is registered. Here, in a case where a single system model corresponding to the model ID includes a plurality of system models (for example, requirement model, part model, or the like), information indicating a type of each submodel is registered, as assuming each system model as a submodel. For example, in the example in FIG. 2A, it is indicated that a type of a system model of M001 is the “requirement model”, and a type of a system model of M003 includes two submodels including the “requirement model” and the “part model”.

In the description of the model, information indicating features of each system model or the like is registered. Specifically, in the description of the model, information having various contents such as a use scene of each system model, constraint conditions, a role, attention on use, a relationship (for example, dependency relationship, aggregation relationship, or the like) and a combination with other system models or subsystems is registered.

In the model description language, information describing each system model in a modeling language is registered. Note that, the model description language is, for example, a unified modeling language (UML), a systems modeling language (SysML), or the like.

In the necessary information, information necessary for generating the system model is registered. Specifically, in the necessary information, a type and content of design information necessary when the system model is generated are registered. For example, in a case of the system model of M001 (requirement model), “structured data describing required specifications of a product” is registered as the information necessary for generating the system model.

FIGS. 2B-1 to 2B-3 are diagrams illustrating an example of information registered in the image of the model. As illustrated, in the image of the model, a visualized image of the system model (for example, diagram indicating block diagram of system model) is registered. Note that, in the block diagram of the system model, information such as a block in which information extracted from the design information is embedded and displayed or its position is defined in the model description language in advance.

The information extraction model database 143 stores an information extraction model that extracts the information necessary for generating the system model from the design information database 141. Specifically, the information extraction model database 143 stores an information model using a machine learning algorithm represented by generative artificial intelligence (AI) and a neural network as the information extraction model. Note that the type of the information model is, for example, a large language model (LLM) or the like. Hereinafter, a case will be described where the generative AI is used as the information extraction model.

Note that the information extraction model extracts the information necessary for generating the system model from the design information database 141, using the predetermined prompt specified based on the analysis result of the user input information.

The prompt database 144 stores a prompt of an instruction or a request to be input to the information extraction model. These prompts having various contents are prepared in advance, so that the information extraction model can accurately extract appropriate information according to the user input information from the design information database 141.

Next, the processing unit 150 will be described. The processing unit 150 is a functional unit that executes various types of processing executed by the design support system 1000. Specifically, the processing unit 150 includes an input information analysis unit 151, a model candidate specifying unit 152, an information extraction unit 153, and a system model generation unit 154, as an individual functional unit that executes each processing.

The input information analysis unit 151 is a functional unit that analyzes the user input information regarding the system model. Specifically, the input information analysis unit 151 acquires the user input information via the input reception unit 110 and executes natural language analysis processing (hereinafter, may be referred to as natural language processing) so as to specify (extract) information regarding the type of the system model and information regarding a target of the system model from the user input information. Note that, in a case where the user input information is input by the voice input, the input information analysis unit 151 converts voice information into text information and executes the natural language processing using the text information.

The natural language processing can be implemented by performing fine tuning of name entity recognition (NER) related to the system model or the design information, for example, using a bidirectional encoder representations from transformers (BERT) model.

The model candidate specifying unit 152 is a functional unit that specifies (select) a candidate of the system model. The model candidate specifying unit 152 specifies an appropriate candidate of the system model from the system model database 142, based on the specified information regarding the type of the system model.

The information extraction unit 153 is a functional unit that extracts the information necessary for generating the system model from the design information database 141, using the information extraction model.

The system model generation unit 154 is a functional unit that generates the system model using the template of the system model. Specifically, the system model generation unit 154 generates the system model by embedding the necessary information extracted by the information extraction unit 153, in a predetermined position defined by the selected template of the system model.

An example of the functional configuration of the design support system 1000 has been described above.

### <Description of Processing>

Next, design support processing executed by the design support system 1000 will be described.

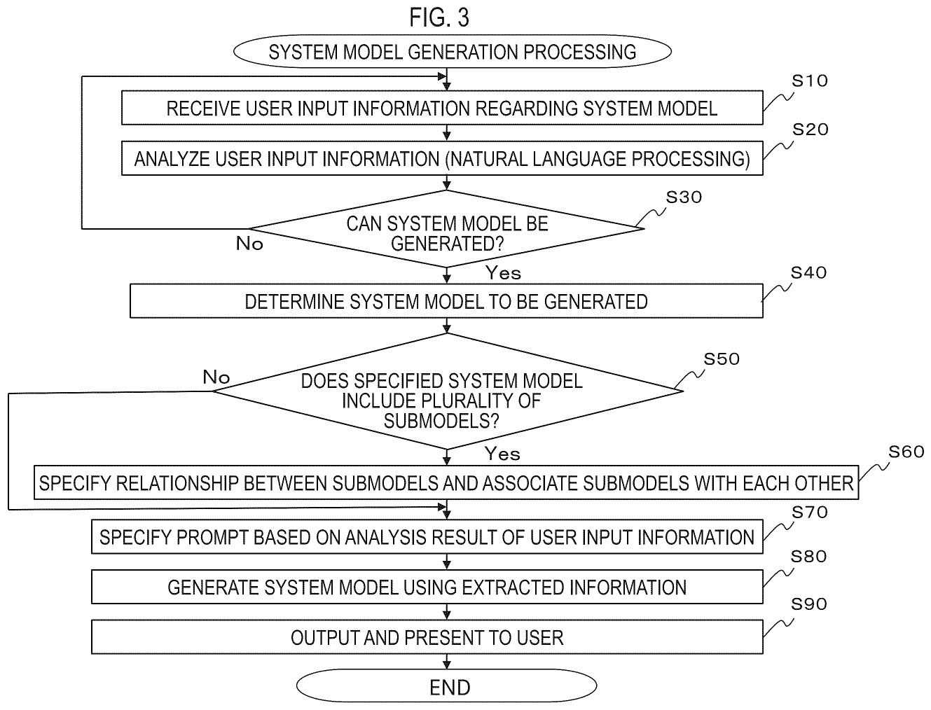

FIG. 3 is a flowchart illustrating an example of the design support processing. Note that the design support processing starts, for example, when the input reception unit 110 receives an execution instruction of the processing from the user.

When the processing starts, the input reception unit 110 receives the user input information regarding the system model (step S10).

Next, the input information analysis unit 151 analyzes the user input information (step S20). Specifically, the input information analysis unit 151 analyzes the user input information by the natural language processing and specifies the information regarding the type of the system model and the information regarding the target of the system model.

Note that the information regarding the type of the system model is information indicating a type of a system model estimated from the analysis result of the user input information. For example, in a case where the user input information has content such that “it is desired to check a function defined by a digital camera”, the input information analysis unit 151 specifies a “functional model (functional block diagram)” as the information regarding the type of the system model, based on the natural language processing. Furthermore, for example, in a case where the user input information has content such that “it is desired to see a relationship between required specifications related to safety and related parts together, when designing a digital camera”, the input information analysis unit 151 specifies the “requirement model (requirement block diagram) and the part model (part block diagram)” as the information regarding the type of the system model, based on the natural language processing.

Furthermore, the information regarding the target of the system model is information necessary when the system model is generated. For example, in a case where the user input information has content such that “it is desired to check a function defined by a digital camera”, the input information analysis unit 151 specifies the “function definition document” as the information regarding the target of the system model, based on the natural language processing. Furthermore, for example, in a case where the user input information has content such that “it is desired to see a relationship between required specifications related to safety and related parts together, when designing a digital camera”, the input information analysis unit 151 specifies content as the “required specifications related to safety for the requirement model (requirement block diagram) and the information associated with the requirement model (requirement block diagram) for the part model (part block diagram)” as the information regarding the target of the system model, based on the natural language processing.

Next, the model candidate specifying unit 152 determines whether or not the system model can be generated (step S30). Specifically, in a case where the template of the system model registered in the system model information 200 can be specified based on the information regarding the type of the system model, the model candidate specifying unit 152 determines that the system model can be generated, and in a case where it is not possible to specify the template of the system model, the model candidate specifying unit 152 determines that it is not possible (not capable) to generate the system model.

More specifically, in a case where the model candidate specifying unit 152 calculates a similarity between the information regarding the type of the system model and the information registered in the description of the model in the system model information 200 and there is a system model having a similarity equal to or more than a predetermined value, the model candidate specifying unit 152 determines that the system model can be specified from the system model information 200 and the system model can be generated. Note that, for example, a cosine similarity is used to calculate the similarity.

Then, in a case of determining that it is not possible (not capable) to generate the system model (No in step S30), the model candidate specifying unit 152 returns the processing to step S10. At this time, for example, the model candidate specifying unit 152 displays a message requesting the user to input the user input information again (for example, “The type of the system model cannot be specified from input information. Please input additional information” or the like) on the output device, via the output information generation unit 120.

Furthermore, in a case of determining that the system model can be generated (Yes in step S30), the model candidate specifying unit 152 determines a system model to be generated (step S40) and proceeds the processing to step S50. Specifically, in a case where the number of system models determined to be generable in step S30 is one, the model candidate specifying unit 152 determines the system model as the system model to be generated.

Furthermore, in a case where there is the plurality of system models determined to be generable in step S30, the model candidate specifying unit 152 determines a system model having the highest similarity as the system model to be generated. Alternatively, the model candidate specifying unit 152 may present image information (image of model in FIG. 2B) indicating the image of the plurality of system models determined to be generatable to the user and determine a system model selected by the user as the system model to be generated.

Next, the model candidate specifying unit 152 determines whether or not the specified system model includes the plurality of submodels (step S50). Then, in a case of determining that the plurality of submodels is included (Yes in step S50), the model candidate specifying unit 152 proceeds the processing to step S60. On the other hand, in a case of determining that the plurality of submodels is not included (No in step S50), the model candidate specifying unit 152 proceeds the processing to step S70. Note that whether or not the system model includes the plurality of submodels can be specified, for example, by referring to an item of the system model/submodel of the system model information 200.

In step S60, the model candidate specifying unit 152 specifies a relationship between the submodels based on the information registered in the description of the model in the system model information 200 and associates the submodels with each other. Note that the relationship between the submodels includes, for example, a dependency relationship, an aggregation relationship, a composite relationship, a generalization relationship, or the like.

The dependency relationship indicates a relationship in which one submodel depends on another submodel. The aggregation relationship indicates a relationship in which a plurality of submodels are gathered to form a new submodel. The composite relationship indicates a relationship in which a plurality of submodels are combined to form a new submodel. Note that, in the composite relationship, a relationship between the submodels has stronger connection. The generalization relationship indicates an inheritance relationship between submodels. The generalization relationship indicates that a higher-order model element generalizes a lower-order model element.

Such a relationship between the submodels is registered in the description of the model in the system model information 200 in advance.

In step S70, the information extraction unit 153 specifies the prompt to be input to the information extraction model, based on the analysis result of the user input information. Specifically, the information extraction unit 153 specifies an appropriate prompt to be input to the information extraction model, from the prompt database 144, based on the information regarding the target of the system model specified in step S20.

More specifically, the information extraction unit 153 calculates a similarity between the information regarding the target of the system model and each prompt stored in the prompt database 144 and specifies a prompt having the highest similarity as the prompt to be input to the information extraction model. Note that, for example, it is sufficient to use the cosine similarity to calculate the similarity.

Furthermore, the information extraction unit 153 extracts (acquire) the information necessary for generating the system model from the design information, by inputting the specified prompt to the information extraction model (generative AI). For example, in a case where the information regarding the target of the system model specified by the natural language processing of the user input information is the “function definition document”, for example, the information extraction unit 153 specifies a prompt such as “Please read the function definition document of the digital camera and list functions of the digital camera”, from the prompt database 144. Furthermore, the information extraction unit 153 acquires the information necessary for generating the system model from the design information database 141, by inputting this to the information extraction model.

Furthermore, for example, in a case where the information regarding the target of the system model has content such that “required specifications related to safety for requirement model (requirement block diagram), and information associated with requirement model (requirement block diagram) for part model (part block diagram)”, the information extraction unit 153 specifies a prompt, for example, “Please list required specifications related to safety of product” and “Please extract information regarding part model associated with requirement model” from the prompt database 144. Furthermore, the information extraction unit 153 acquires the information necessary for generating the system model from the design information database 141, by inputting these to the information extraction model.

Note that, by the processing of the information extraction unit 153 using such an information extraction model, for a prompt such as “Please read the function definition document of the digital camera and list functions of the digital camera”, for example, information such as “(function 1) screen capture: image a subject and save as a digital image, with a basic function”, “(function 2) power management: display a battery charging status and switch to a power saving mode”, or “(function 3) image display: check an imaged photograph or video on a liquid crystal screen of a camera” is extracted.

Next, the system model generation unit 154 generates the system model using the extracted information (step S80). Specifically, the system model generation unit 154 generates the system model by embedding the extracted information in the predetermined position defined by the template of the system model determined in step S40. Furthermore, when the system model generation unit 154 presents the generated system model to the user by displaying the system model to a predetermined output device (step S90), the system model generation unit 154 ends this flow.

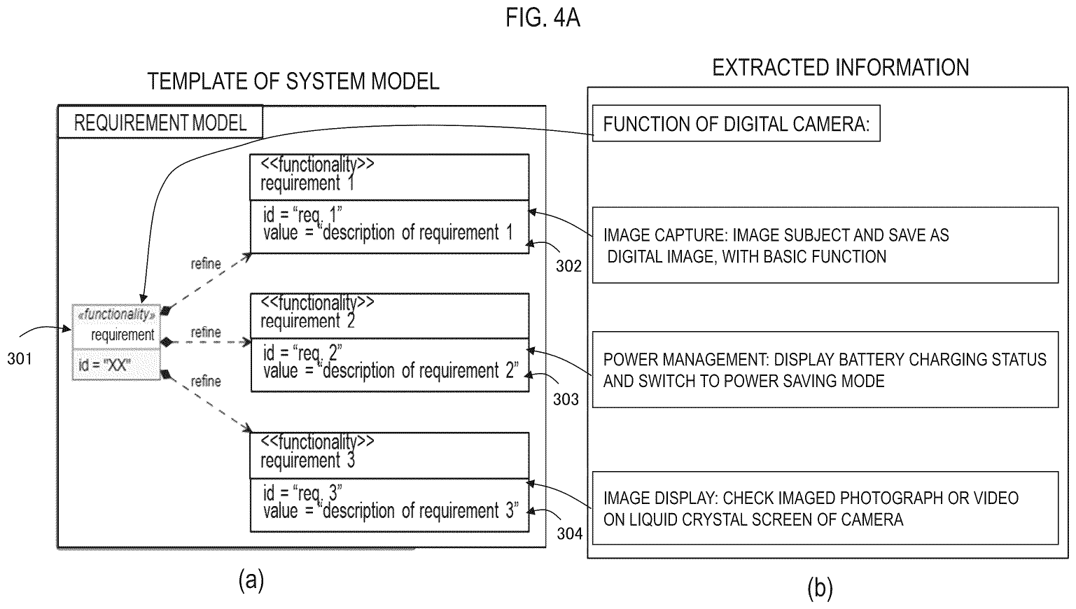

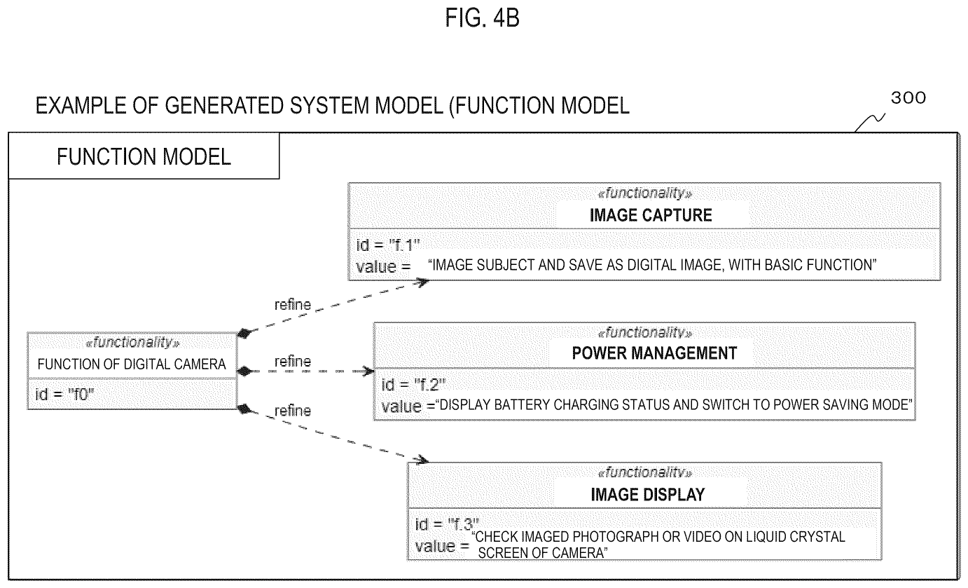

FIG. 4A is a diagram for explaining generation of a system model according to an example. Left side (a) of FIG. 4A illustrates an example of an image of the system model determined in step S40, and right side (b) of FIG. 4A illustrates an example of information extracted based on the prompt.

The system model generation unit 154 executes processing for embedding the extracted information (information regarding functions 1 to 3 of digital camera in present embodiment) in the predetermined position defined by the template of the system model. Specifically, the system model generation unit 154 executes processing for embedding the “function of the digital camera” to a corresponding portion 301 of the template and embedding pieces of the extracted information (functions 1 to 3) to respectively corresponding portions 302 to 304 of the template. Note that, in a case where a type and an embedding position of the information are defined by the template, the processing for embedding the extracted information to the corresponding position is known. Therefore, detailed description is omitted. The system model generation unit 154 generates the system model, based on the execution of such processing.

FIG. 4B is a diagram illustrating an example of the system model generated in the processing in step S80. As illustrated, the system model is generated by embedding the extracted information to the predetermined position defined by the template of the system model.

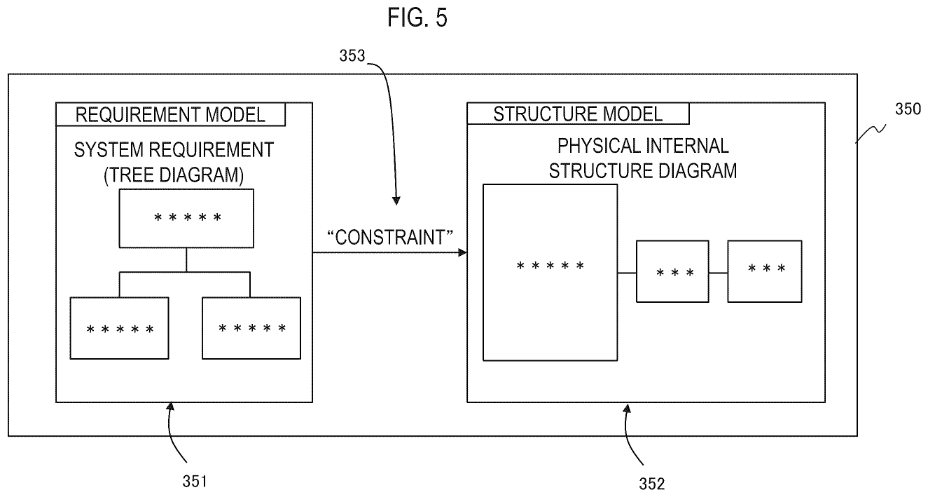

FIG. 5 is a diagram for explaining an example of a case where a system model including a plurality of submodels is generated. Similarly, an illustrated system model 350 is generated by embedding various types of information extracted from the design information database 141 based on the prompt in a predetermined position of a submodel defined by a template of the system model 350. Furthermore, since this system model includes the plurality of submodels (requirement model 351 and structural model 352), the system model generation unit 154 associates the relationship (“constraint” relationship in illustrated example) between the submodels specified in step S60. Note that an embedding position of information 353 indicating the relationship between the submodels is also defined by the template in advance.

The design support processing has been described above.

According to such a design support system, it is possible to reduce the load of the user related to the creation of the system model and generate an appropriate system model according to the user's intention. In particular, the user can obtain an appropriate system model, only by inputting the instruction or the request regarding the system model in the natural language into the design support system, without requiring specialized knowledge. Such a design support system can greatly contribute to the generation of the system model.

### Second Embodiment

A design support system 1000 according to the present embodiment generates an appropriate system model according to a user's intention, in consideration of an attribute of a user. Specifically, the design support system 1000 acquires user input information including the attribute of the user, and generates the system model according to the user's intention, using an appropriate template of a system model according to the attribute of the user, based on comparison with description of a model in system model information 200.

Note that, in the present embodiment, it is assumed that information regarding the attribute of the user be registered in the description of the model in the system model information 200, in advance. Furthermore, the attribute of the user represents identification and expertise of an individual or a group involved in product design and includes, for example, a specialized field, a role, a responsible range, a skill level, or the like of the user.

The specialized field is information indicating specialized knowledge and a technical area of the user who is a designer, and includes, for example, an electrical designer, a machine designer, a software designer, or the like. The role is information indicating a specific role that the user is in charge in a design process, and includes, for example, a principal designer, a subsystem designer, an integration designer, or the like. The responsible range is information indicating a range where the user is responsible or makes a determination, and includes, for example, design of some subsystems, design of a specific function, design of an entire system, or the like. The skill level is information indicating a level of experience and an ability of the user, and includes, for example, a beginner designer, an intermediate designer, an advanced designer, or the like.

Furthermore, in the description of the model in the system model information 200, information corresponding to these user attributes, for example, information that makes it easier to select the system model according to the user attribute such as “this system model is a system model for a beginner designer” or “this system model is a system model that is often used by an electrical designer” is registered.

When an input reception unit 110 of the design support system 1000 acquires the user input information including the user attribute, a model candidate specifying unit 152 calculates a similarity between an analysis result of the user input information and the description of the model in the system model information 200 as in the embodiment described above and specifies an appropriate template of the system model (step S40).

In this case, an input information analysis unit 151 obtains the analysis result including the user attribute (information regarding type of system model), by natural language processing. Furthermore, the model candidate specifying unit 152 calculates a similarity with the description of the model in the system model information 200 using the “information regarding type of system model” including the user attribute and selects a system model with a high similarity. As a result, the system model in which the user attribute is considered is determined as a system model to be generated.

According to such a design support system, the system model of a template more suitable for the user can be generated, in consideration of the user attribute. For example, in a case where the user is an electrical designer, it is considered that it is preferable for the design support system to generate a system model that the electrical designer often uses. Furthermore, in a case where the user is a beginner designer, it is considered that it is preferable for the design support system to generate a system model that the beginner designer often uses according to the skill level. The design support system according to the present embodiment can generate the system model according to the user's intention, by considering such user attributes.

### <Modification>

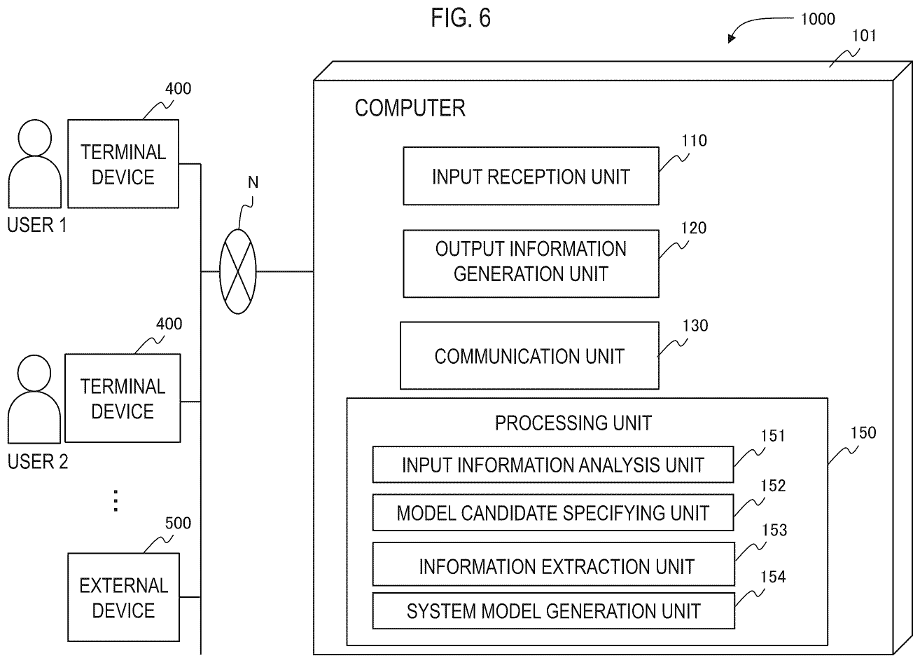

Note that the design support system 1000 is not limited to the form in FIG. 1 and can be variously modified. An example of the configuration is illustrated in FIG. 6. Note that components and functions same as those in FIG. 1 are denoted with the same reference numerals, and detailed description is omitted.

FIG. 6 is a diagram illustrating an example of a schematic configuration of the design support system 1000 according to the modification. As illustrated, the design support system 1000 includes a computer 101, a terminal device 400, and an external device 500, and these devices are communicably connected to each other via a predetermined network N. Note that the network N is, for example, a communication network such as the Internet, a local area network (LAN), or a wide area network (WAN).

Although a basic configuration of the computer 101 is similar to that in the embodiment described above, the basic configuration is different from that in the embodiment in that a storage unit 140 that stores various databases is not included. In the present modification, various databases stored in the storage unit 140 in FIG. 1 are stored in the external device 500.

The terminal device 400 is the terminal device 400 used by the user who is a designer, and is, for example, a personal computer, a smartphone, a tablet terminal, or the like. The user inputs the user input information via the terminal device 400.

The external device 500 is, for example, a computer such as a server device placed on a cloud. Furthermore, the external device 500 includes each database in the storage unit 140 included in the computer 100 in FIG. 1.

The computer 101 of the design support system 1000 according to the modification acquires the user input information via the terminal device 400. Furthermore, the computer 101 appropriately acquires various types of information from the external device 500, according to processing. Furthermore, the computer 101 displays screen information of the generated system model on a display included in the terminal device 400.

Even with the design support system having such a form, as in the embodiment described above, it is possible to reduce a load of the user by reducing the number of man-hours of the user related to creation of the system model and to realize improvement in a design efficiency and reduction in a design process period.

Furthermore, in the embodiment described above, the predetermined prompt is specified from the prompt database 144 based on the analysis result of the user input information. However, the present invention is not limited to this, and an appropriate prompt may be automatically generated by the generative AI. Specifically, the design support system 1000 may cause the generative AI to generate a prompt that allows the information extraction model to accurately extract the necessary information, using the user input information.

According to such a design support system, it is not necessary to prepare the prompt in advance, and it is possible to appropriately generate an appropriate prompt based on the user input information by the generative AI. As a result, the design support system can more accurately extract the necessary information according to the user's intention from the design information database.

### <Hardware Configuration of Design Support System 1000>

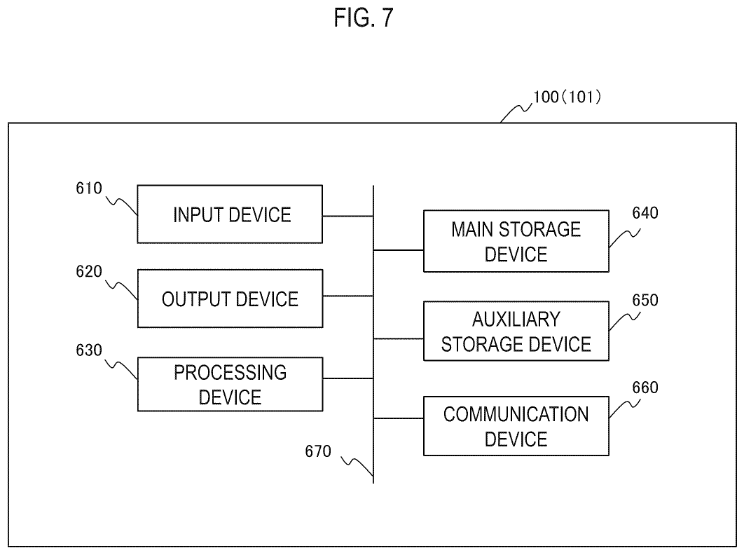

FIG. 7 is a diagram illustrating an example of a hardware configuration of the design support system 1000. As illustrated, the design support system 1000 includes an input device 610, an output device 620, a processing device 630, a main storage device 640, an auxiliary storage device 650, a communication device 660, and a bus 670 that electrically connects these devices to each other.

The input device 610 is, for example, an input device such as a touch panel, a keyboard, or a mouse. The output device 620 is a display device such as a liquid crystal display or an organic display.

The processing device 630 is, for example, a processor such as a central processing unit (CPU) or a graphics processing unit (GPU). The main storage device 640 is a memory device (memory resource) such as a random access memory (RAM) or a read only memory (ROM). Note that the design support system 1000 includes at least one or more processors and memory resources.

The auxiliary storage device 650 is a non-volatile storage device such as a so-called hard disk drive that can store digital information, a solid state drive (SSD), or a flash memory.

The communication device 660 is a wired communication device that performs wired communication via a network cable or a wireless communication device that performs wireless communication via an antenna.

An example of the hardware configuration of the design support system 1000 has been described above.

The processing unit 150 of such a design support system 1000 is implemented by a program that causes the processing device 630 to execute processing. This program is stored in the main storage device 640 or the auxiliary storage device 650, loaded on the main storage device 640 when the program is executed, and is executed by the processing device 630.

Furthermore, the storage unit 140 is implemented by the main storage device 640, the auxiliary storage device 650, or a combination thereof. Furthermore, the communication unit 130 is implemented by the communication device 660.

Furthermore, the configurations, the functions, the processing unit 150, processing means, or the like of the design support system 1000 may be implemented, for example, by hardware by designing some or all of these by an integrated circuit. Furthermore, the configurations and the functions may be implemented by software by interpreting and executing a program that implements each function, by the processor. Information such as a program, a table, or a file for implementing each function can be placed on a storage device such as a memory, a hard disk, or an SSD or a recording medium such as an IC card, an SD card, or a DVD.

Furthermore, the present invention is not limited to the embodiments and the modification described above and includes various modifications within the scope of the same technical idea. For example, the embodiments described above have described in detail for each understanding of the present invention, and are not limited to those necessarily including all the components described above. Furthermore, some components of the embodiment can be replaced with the components of another embodiment, and in addition, the components of the another embodiment can be added to the components of the embodiment. Furthermore, other components can be added to, deleted from, or replaced with some components of each embodiment.

Furthermore, in the above description, control lines and information lines considered to be necessary for the description are indicated, and all the control lines and information lines in a product are not necessary indicated. In practice, it can be considered that almost all the components are connected to each other.

What is claimed is:

1. A design support system comprising:
an input information analysis unit configured to analyze input information a user regarding a system model;
a model candidate specifying unit configured to specify a system model to be generated from system model information in which a plurality of types of templates of the system models is registered, based on an analysis result of the input information;
an information extraction unit configured to extract necessary information used to generate the system model from a database that stores information regarding design, based on the analysis result of the input information; and
a system model generation unit configured to generate a system model according to the input information, using the extracted necessary information and a template of the system model to be generated.

2. The design support system according to claim 1, wherein
a relationship between submodels included in the system model is registered in the system model information, and
the model candidate specifying unit,
in a case where the system model to be generated includes a plurality of submodels, specifies the relationship between the submodels using the system model information and associates with each other.

3. The design support system according to claim 1, wherein
information regarding an attribute of the user is registered in the system model information,
the input information analysis unit analyzes the input information including the information regarding the attribute of the user, and
the model candidate specifying unit specifies a template of the system model in consideration of the attribute of the user from the system model information, based on the analysis result of the input information.

4. The design support system according to claim 1, wherein
the model candidate specifying unit
specifies the system model to be generated from the system model information, based on a similarity between content registered in the system model information and the analysis result of the input information.

5. The design support system according to claim 1, wherein
the input information analysis unit
analyzes the input information of the user by natural language processing.

6. The design support system according to claim 1, wherein
image information indicating an image of each system model is registered in the system model information, and
the model candidate specifying unit,
in a case where there is a plurality of candidates of the system model to be generated, presents the image information of the image corresponding to the candidate system model to the user, using the system model information and specifies a candidate of the system model selected by the user as the system model to be generated.

7. The design support system according to claim 1, wherein
the information extraction unit extracts the necessary information from the database, using an information extraction model that is an information model generated based on generative artificial intelligence (AI) or machine learning.

8. The design support system according to claim 7, wherein
the information extraction unit
specifies a prompt to be input to the information extraction model based on the analysis result of the input information, and
extracts the necessary information by inputting the specified prompt to the information extraction model.

9. The design support system according to claim 1, wherein
the system model is model-based systems engineering (MBSE).

10. The design support system according to claim 2, wherein
the relationship between the submodels is a dependency relationship, an aggregation relationship, a composite relationship, or a generalization relationship.

11. The design support system according to claim 3, wherein
the information regarding the attribute of the user is a specialized field, a role, a responsible range, or a skill level of the user.

12. A design support method executed by a design support system, wherein
the design support system performs
an input information analysis step of analyzing input information of a user regarding a system model,
a model candidate specifying step of specifying a system model to be generated from system model information in which a plurality of types of templates of the system models is registered, based on an analysis result of the input information,
an information extraction step of extracting necessary information used to generate the system model from a database that stores information regarding design, based on the analysis result of the input information, and
a system model generation step of generating a system model according to the input information, using the extracted necessary information and the template of the system model to be generated.

13. A program for causing a computer to function as a design support system, the program causes the computer to function as:
an input information analysis unit that analyzes input information a user regarding a system model;
a model candidate specifying unit that specifies a system model to be generated from system model information in which a plurality of types of templates of the system models is registered, based on an analysis result of the input information;
an information extraction unit that extracts necessary information used to generate the system model from a database that stores information regarding design, based on the analysis result of the input information; and
a system model generation unit that generates a system model according to the input information, using the extracted necessary information and the template of the system model to be generated.
